(19) United States
(12) Patent Application Publication
(10) Pub. No.: US 2010/0044222 A1
(43) Pub. Date: Feb. 25, 2010

(54) Sputtering target including magnetic field uniformity enhancing sputtering target backing tube

(75) Inventors: Greg Miller, DeWitt, IA (US); Donald V. Jacobson, Saline, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp.,, Auburn Hills, MI (US)

(21) Appl. No.: 12/230,035

(22) Filed: Aug. 21, 2008

(51) Int. Cl. C23C 14/35

(52) U.S. Cl. 204/298.12; 204/298.22

(57) ABSTRACT

Certain example embodiments relate to sputtering target backing tube that are slightly ferromagnetic, thereby providing small-scale shunting that reduces the occurrence or magnitude of short-range magnetic field deviations during magnetron sputtering with cylindrical sputtering targets. For example, backing tube allows may be carefully optimized to be somewhat ferromagnetic, thereby enhancing the uniformity of the magnetic field generated by the magnet bar. In certain example embodiments, short range magnetic field deviations may be reduced to less than about 5% from average, more preferably less than about 2% from average, and still more preferably less than about 1% from average. Such short range magnetic field deviation reducing target backing tubes may be used in along with, or in place of, shims or shunts that address long range magnetic field deviations.

### FIELD OF THE INVENTION

Certain example embodiments of this invention relate to rotating sputtering targets. More particularly, certain example embodiments of this invention relate to magnetic field uniformity enhancing sputtering target backing tubes that may be used with rotating sputtering targets, and/or methods of making the same. In certain example embodiments, the sputtering target backing tube may be slightly ferromagnetic to provide small-scale shunting, thereby reducing the occurrence of short-range magnetic field deviations. In certain example embodiments, backing tube alloys may be carefully optimized to be somewhat ferromagnetic, thereby enhancing the uniformity of the magnetic field generated by the magnet bar in magnetron sputtering with cylindrical sputtering targets.

### BACKGROUND AND SUMMARY OF EXAMPLE EMBODIMENTS OF THE INVENTION

The use of sputtering in order to deposit coatings on substrates is known in the art. For example, and without limitation, see U.S. Pat. Nos. 5,403,458; 5,317,006; 5,527,439; 5,591,314; 5,262,032; and 5,284,564, the entire contents of each of which are hereby incorporated herein by reference. Briefly, sputter coating is an electric-discharge-type process which is conducted in a vacuum chamber in the presence of at least one gas. Typically, a sputtering apparatus includes a vacuum chamber, a power source, an anode, and one or more cathode targets which include material used to create a coating on an adjacent substrate (e.g., glass substrate or substrate of other material). The target may include an outer tube enclosing a magnet bar assembly including and an associated inner magnet bar support tube. More specifically, in certain known arrangements, the one or more magnet bars are secured to the underside of the support tube along substantially the entire length of the support tube. In certain example instances, the magnet bar may also include the support tube.

When an electrical potential is applied to the cathode target, the gas forms a plasma that bombards the target, thereby causing particles of the sputtering material from the target to leave the exterior surface of the target. These particles fall onto the substrate to form the coating thereon. The outer target tube typically rotates about the stationary magnets which are supported by the inner support tube so that particles are “sputtered” uniformly from the substantially the entire periphery of the target tube as it rotates past the fixed magnet bar(s).

As is known, the inclusion of magnet bars within target tubes enhances deposition rates. It is desirable to create substantially uniform magnetic fields, as a substantially uniform magnetic field generally leads to a more uniform coating on the substrate. Unfortunately, as stronger magnet bars are added to a target tube, deviations in the magnetic field uniformity become more and more likely, thus potentially leading to deviations in the uniformity of the coating. Such deviations in the uniformity generally are seen as disadvantageous. It is noted that some variations in magnetic field density sometimes are related to manufacturing imperfections in the magnet bars, misalignment of the magnet bars, and/or other factors.

More particularly, sputtering magnet bars exhibit long range and short range magnetic field deviations that affect sputtered film uniformity. Long range magnetic field deviations sometimes are addressed by shims, with such shimming mechanisms typically being integral to the magnet bars. That is, conventional sputtering targets often include magnetic shims (e.g., functioning as means to adjust the magnetic field). Thus, magnetic field strength also may be adjusted by adding and/or removing shims to change the height, e.g., adjusting the magnet-to-target distance. Similarly, shimming can be adjusted by tightening or loosening one or more screws that may run the length of the tube, e.g., adjusting the magnet-to-target distance. Adjusting the physical height of the magnet(s) may cause a corresponding adjustment to the magnet field created by the sputtering target. Accordingly, the distance between the outer diameter of the target tube and the magnet bar can be adjusted so as to alter the magnetic field. This adjustment process is sometimes referred to as “tuning.”

Some commercially available magnet bars include approximately 5-6 bolt locations along a 10-12 foot magnet bar, enabling shims to be added or removed at these locations. For example, Applied Material's “X-Bar” magnet bar has a magnetic field adjustment shim spacing of 17.5 inches. Oftentimes, this sort of shimming effectively reduces long range magnetic field deviations.

Unfortunately, however, short range magnetic field variations generally cannot be resolved through the use of shims, as an unmanageable number of shim positions would have to be provided along the length of the magnet bar. Indeed, any kind of fine-tuning is difficult because a large, typically rigid element is being adjusted. Accordingly, tuning conventional long magnet bars (which typically extend the length of the target) tends to be comparatively less precise and may alter the magnetic field produced in potentially unpredictable and/or undesirable ways. As noted above, it is difficult if not impossible to address short range magnetic field deviations in a commercially viable way through conventional shimming mechanisms. For example, even Applied Material's “X-Bar” magnet bar cannot reasonably and reliably correct short range magnetic field deviations less than about 17.5 inches.

To this end, FIG. 1 is a graph of the magnetic field strength of a magnetic bar, showing both long and short range magnetic field deviations of such a system. FIG. 1 plots the total field in milliTeslas (mT) vs. position in inches. The measured magnetic field strength is given as line 102, with the average magnetic field strength throughout the length of interest being shown as line 104. Lines 106a and 106b respectively demarcate 2% above and below of the average. As can be seen from FIG. 1, there is a sizable magnetic field deviation along a substantial length of the measured magnetic field.

As used herein, “short range” implies a distance smaller than that between adjacent screws, shims, or other known adjustment mechanisms. Typically, adjacent adjustment mechanisms are located about 2 feet apart, as noted above. In implementations that do not include such adjustment mechanisms, it is understood that “short range” implies a distance of less than about 1-2 feet. Similarly, as used herein, “long range” implies a distance greater than adjacent screws, shims, or other known adjustment mechanisms. In implementations that do not include such adjustment mechanisms, it is understood that “long range” implies a distance of greater than about 1-2 feet.

Thus, it will be appreciated that there is a need in the art for a sputtering apparatus and/or a method of making the same that address(es) short range magnetic field deviations and/or lead(s) to a more uniform magnetic field being produced.

Certain example embodiments of this invention provide magnetic field uniformity enhancing sputtering target backing tubes that may be used with a rotating sputtering targets. In certain example embodiments, the sputtering target backing tube may be slightly ferromagnetic to provide small-scale shunting, thereby reducing the occurrence of short-range magnetic field deviations. In certain example embodiments, backing tube alloys may be carefully optimized to be somewhat ferromagnetic, thereby enhancing the uniformity of the magnetic field generated by the magnet bar in magnetron sputtering with cylindrical sputtering targets.

In certain example embodiments of this invention, a rotatable magnetron sputtering target is provided. A rotatable target tube comprises a target backing tube having sputtering material supported by an outer surface thereof to be sputter deposited on a substrate. The target backing tube is at least partially ferromagnetic. A magnet bar structure is provided within the rotatable target tube. The magnet bar structure is stationary when the rotatable tube is rotating during sputtering. The target backing tube and the magnet bar structure are arranged to cooperate in producing a substantially uniform magnetic field during sputtering.

In certain example embodiments, a rotatable magnetron sputtering target is provided. A rotatable target tube comprises a target backing tube having sputtering material supported by an outer surface thereof to be sputter deposited on a substrate. The target backing tube is at least partially ferromagnetic. A magnet bar structure is provided within the rotatable target tube. The magnet bar structure is stationary when the rotatable tube is rotating during sputtering. At least one adjustment mechanism is configured to alter a distance between at least a portion of the magnet bar structure and the sputtering material. The at least one screw or shim adjustment mechanism and the magnet bar structure are arranged to cooperate during sputtering to (a) improve or increase long range magnetic field uniformity and (b) reduce long range magnetic field deviations. The target backing tube and the magnet bar structure are arranged to cooperate during sputtering to (a) improve or increase short range magnetic field uniformity and (b) reduce short range magnetic field deviations.

In certain example embodiments where long range magnetic field adjustment mechanisms are provided, a magnetic permeability of the target backing tube material may be configured to reduce magnetic field deviations between adjacent ones of said adjustment mechanisms. In certain example embodiments, the target backing tube material preferably will have a magnetic permeability suitable for adjusting the magnetic field uniformity within about 2 ft., and more preferably within about 1 foot. In certain example embodiments, the target backing tube material preferably will be suitable for reducing short range magnetic field deviations to less than about 2% from the average magnetic field deviation, more preferably less than about 1% from the average magnetic field deviation.

The features, aspects, advantages, and example embodiments described herein may be combined to realize yet further embodiments.

### BRIEF DESCRIPTION OF THE DRAWINGS

These and other features and advantages will be better and more completely understood by reference to the following detailed description of exemplary illustrative embodiments in conjunction with the drawings, of which:

FIG. 1 is a graph of the magnetic field strength of a magnet bar, showing both long and short range magnetic field deviations;

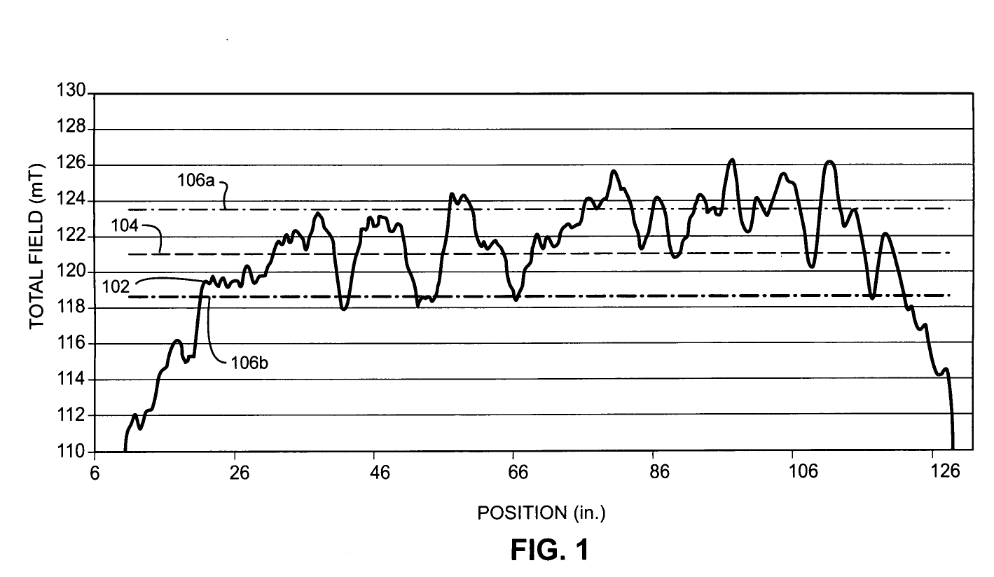

FIG. 2 is a simplified and partially schematic side elevation of a sputtering apparatus; and

FIG. 3 shows a side cross-section of a magnet bar structure in accordance with an example embodiment.

### DETAILED DESCRIPTION OF EXAMPLE EMBODIMENTS OF THE INVENTION

In certain example embodiments of this invention, a rotatable magnetron sputtering target is provided. A rotatable target tube comprises a target backing tube having sputtering material supported by an outer surface thereof to be sputter deposited on a substrate. The target backing tube is at least partially ferromagnetic. A magnet bar structure is provided within the rotatable target tube. The magnet bar structure is stationary when the rotatable tube is rotating during sputtering. The target backing tube and the magnet bar structure are arranged to cooperate in producing a substantially uniform magnetic field during sputtering.

In certain example embodiments, a rotatable magnetron sputtering target is provided. A rotatable target tube comprises a target backing tube having sputtering material supported by an outer surface thereof to be sputter deposited on a substrate. The target backing tube is at least partially ferromagnetic. A magnet bar structure is provided within the rotatable target tube. The magnet bar structure is stationary when the rotatable tube is rotating during sputtering. At least one adjustment mechanism is configured to alter a distance between at least a portion of the magnet bar structure and the sputtering material. The at least one screw or shim adjustment mechanism and the magnet bar structure are arranged to cooperate during sputtering to (a) increase long range magnetic field uniformity and (b) reduce long range magnetic field deviations. The target backing tube and the magnet bar structure are arranged to cooperate during sputtering to (a) increase short range magnetic field uniformity and (b) reduce short range magnetic field deviations.

In certain example embodiments where long range magnetic field adjustment mechanisms are provided, the magnetic permeability of the target backing tube material may be selected to reduce magnetic field deviations between adjacent ones of said adjustment mechanisms. In certain example embodiments, the target backing tube material preferably will have a magnetic permeability suitable for adjusting the magnetic field uniformity within about 2 ft., and more preferably within about 1 foot. In certain example embodiments, the target backing tube material preferably will be suitable for reducing short range magnetic field deviations to less than about 2% from the average magnetic field deviation, more preferably less than about 1% from the average magnetic field deviation.

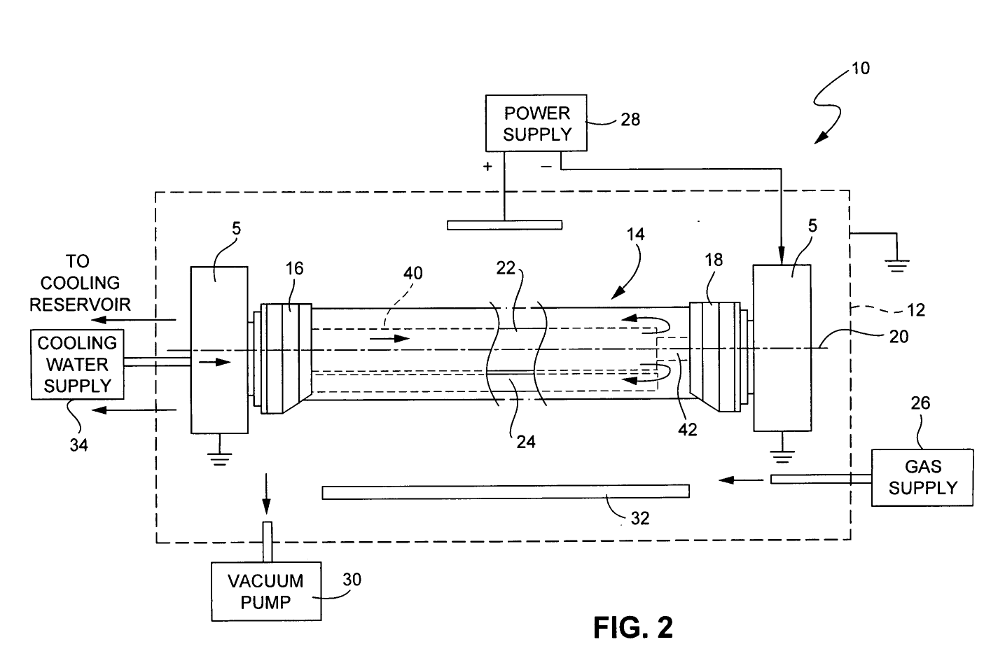

Referring now more particularly to the accompanying drawings in which like reference numerals indicate like parts throughout the several views, FIG. 2 illustrates, in simplified form, a magnetron sputtering apparatus 10. The apparatus includes metal walls 12 of the vacuum chamber in which sputtering is performed; a cylindrical rotating target/tube 14 that is supported at opposite ends by a bearing block 16 and a drive block 18 so that the target is rotatable about axis 20; and an inner stationary magnet bar support tube 22 that supports a magnet carrier and an associated magnet (represented by block 24) that extends along the underside of the inner support tube 22, substantially the entire length of both the inner support tube and the outer target tube. Gas is supplied to the vacuum tube via an external gas supply 26 while power is supplied via external power supply 28. The chamber is evacuated by a vacuum pump 30.

In a typical sputtering process, the plasma formed when an electrical potential is applied to the cathode target bombards the target and the dislodged particles of sputtering material from the target fall onto the substrate 32 to be coated, forming a coating thereon. Throughout the process, the target tube may be cooled to a specified temperature; e.g., cooling water from a source 34 may be introduced into the interior of the hollow inner support tube 22 at one end thereof through the bearing block 16, and may exit the opposite end of the tube through a plurality of nozzle or jet apertures provided in an end plate. The apertures may be arranged to emit streams parallel to the longitudinal axis of the target tube and/or at an acute angle thereto. The cooling water then reverses direction and flows back along the exterior of the inner tube 22, in the chamber or space 40 radially between the inner support tube 22 and the outer rotating target tube 14, exiting the target tube via the same bearing block 16. Note that while the support tube 22 is terminated short of the drive block 18 to permit the cooling fluid to exit the tube and reverse flow through the chamber 40, an inner spindle 42 that may be fixed to the end plate, supports the inner tube in the drive block 18.

In conventional arrangements, an example material that may be used in the tube (other than the magnets themselves) is a nonmagnetic stainless steel alloy.

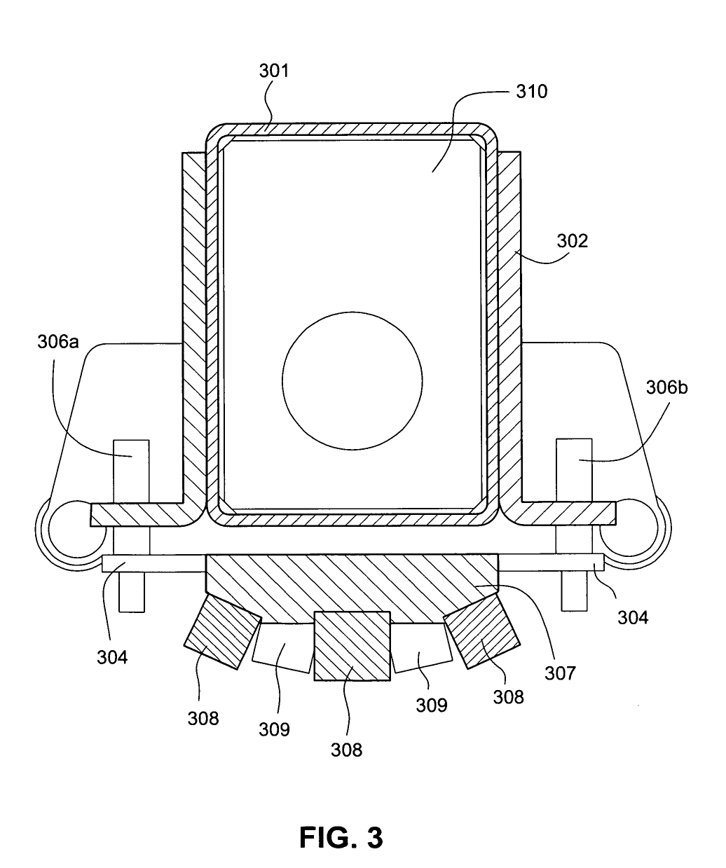

FIG. 3 shows a cross-section of a magnetic bar structure in accordance with an example embodiment. The magnet bar structure of FIG. 3 may be used in connection with a rotating magnetron sputtering apparatus as shown in FIG. 2, where the sputtering tube/target with the sputtering material thereon rotates around the stationary magnet structure.

In FIG. 3, an elongated main mounting part (static profile or support) 302 is mounted on elongated hollow tube 301 and is connected to a magnet carrier support 304 and a magnet carrier or magnet carrier module 307. The hollow portion of tube 301 is indicated at 310. Mounting part 302 may be made up of one or multiple parts in different embodiments, but may include two spaced apart members as shown in FIG. 3 that are provided on opposite sides of tube 301. Magnet carrier 307 is elongated in shape and supports one or more elongated magnet segments 308. Each magnet bar is made up of a plurality of elongated magnet segments 308 arranged in a substantially linear manner, or in series. In other words, a magnet bar may be said to be a row of substantially aligned magnet portions. Immediately adjacent ones of the linearly arranged magnet segments 308 of a given magnet bar may be spaced apart from one another, or alternatively may abut one another, in different example embodiments.

In addition to supporting the magnet segment(s) 308 of the respective magnet bars, the magnet carrier 307 also may optionally support end magnets 309. End magnets 309 are located at one or both ends of the carrier 307, and thus at one or both ends of the bars which are made up of the magnet segments 308. In certain embodiments, a plurality of magnet carrier supports 304 are provided in series on each side of the carrier 307 along the length of the target, with one or more magnet segments 308 being mounted for adjustment via each carrier support 304. Generally, the mounting part 302 extends in a continuous manner along substantially the entire length of each side of tube 301. One or more magnet carriers 307 may be provided along the length of the tube 301 so as to be aligned in series, which each carrier 307 optionally being selectively adjustable with respect to position thereby permitting the position of the magnet segment(s) 308 mounted thereon to be selectively adjusted along with that of 307. In certain example instances, the magnet bar portion of the system may also include the support tube.

Thus, it will be appreciated that there may be provided a rotatable magnetron sputtering target comprising a rotatable target tube (see 14 in FIG. 2) comprising sputtering material on an outer surface thereof to be sputter deposited on a substrate (e.g., onto a glass substrate or the like), a magnet bar structure provided within the rotatable target tube 14, wherein the magnet bar structure is stationary when the rotatable tube 14 is rotating during sputtering, and wherein the magnet bar structure comprises at least one elongated magnet bar which includes a plurality of different magnet segments 308 that are aligned in a substantially linear manner along at least a substantial portion of the magnet bar structure.

In certain example embodiments, the connection between mounting part 302 and magnet carrier support 304 is made using screws 306a-b. However, it will be appreciated that other methods or techniques of attaching mounting part 302 to magnet carrier support 304 may instead be used. It also will be appreciated that mounting part 302 and magnet carrier support 304 may be fixedly attached to each other, although this arrangement might potentially limit the degree to which the magnetic elements 308 can be tuned/adjusted.

According to certain embodiments, turning one of screws 306a-b adjusts the distance between the corresponding magnet segment 308 which is located closest to the screw and tube 301; and optionally turning the other screw which is also located adjacent the segment 308 but across the tube 301 may fix the adjustment. In such an example embodiment, it will be appreciated that the handedness may be reversed such that, for example, screw 306a may be used for adjusting the height and screw 306b may be used for fixing the height, or vice versa. It also will be appreciated that more than two screws may be used to fix each magnetic carrier support 304 to mounting part 302. By adjusting the position of magnet carrier support 304 relative to mounting part 302 using one of the screws, the height/position of magnet bar segment(s) 308 mounted on that particular support 304 will also be adjusted in a desirable manner thereby permitting one to easily adjust the positions of magnet segments and thus adjust the magnetic field to be used during sputtering. Using such an arrangement, the magnetic field may be adjusted for substantial uniformity, at least in terms of the long range magnetic field. For purposes of example and without limitation, one turn of a screw (306a or 306b) in certain example embodiments may translate into about a 0.8 mm adjustment in height of the closest corresponding magnet segment 308. It will be appreciated that in other example embodiments, both of screws 306a-b may be used for height adjustment and/or for fixing the height.

Rollers (not shown) may be mounted, directly or indirectly, on mounting part or support 302 and are arranged to come into rotating contact with the inner wall of the rotating outer tube 14 that supports the target material to be sputtered. Thus, the rollers prevent the inner rotating wall of the target tube (see rotating target tube 14 in FIG. 2 which rotates about axis 20) from contacting or damaging the mounting part 302, tube 301, and magnets 308 and 309. In other words, the rollers may be located in such a way as to prevent or reduce damage to the magnetic elements 308 and 309 and/or the rotating outer tube 14 in case the magnetic elements become too close to the walls of the rotating outer tube 14 as a result of shimming and/or adjustments via screws 306a-b. It will be appreciated that the position of the rollers may also help avoid and/or reduce other potential mechanical influences.

Water may be fed through the magnet bar structure from one side via an inlet and out through the other side via an outlet, for cooling purposes. An example assembly may include several side inlet/outlet holes, as well as a front inlet/outlet hole for water distribution, for purposes of cooling the structure during sputtering operations. This arrangement enables the water or other coolant flow to be varied and more precisely defined, as optional steel components (not shown) may be attached to the holes to vary the sizes thereof, independently and adjustably. In certain example embodiments the inlet/outlet segments may be screwed or otherwise attached to the magnetic segments, potentially providing more opportunities for modifications and/or fine adjustments.

It will be appreciated that magnetic segments 308 are attached to magnet carrier supports and corresponding magnet carrier modules 307. Attaching magnet segments 308 to magnetic carrier modules in this way allows the height of the magnetic segments 308 to be adjusted, as noted above, thus increasing and/or decreasing the magnetic field and sputter rate as desired. One conventional magnet bar tuning method involved the addition of small plates (shims) under a magnet bar extending the length of the target. As noted above, in certain embodiments, a technique for tuning magnet segment 308 positions involves adjustment of one or more screws of the like.

As noted above, short range magnetic field deviations are not reliably and reasonably resolvable with the use of shims. However, the inventors of the instant application have discovered that short range shunting, and thus short range magnetic field tuning, may be provided by optimizing the composition of the target backing tube. A target backing tube is a structural member on which the target material is placed, which may or may not be integral with the rotatable target tube (see 14 in FIG. 2) that supports the sputtering material on the outer surface thereof.

Target backing tubes are, as a standard practice, manufactured from an austenitic (non-magnetic) 300 series stainless steel. Conventionally, the use of stainless steel was seen as a way to keep the backing tube from interfering with the magnetic field. Accordingly, because 300 series stainless steel has low or substantially no magnetic permeability, it has little interference with the magnetic field generated by the magnet bars and thus has been used in conventional target backing tubes. However, as noted above, relying on shims to provide magnetic field adjustment in connection with a non-magnetic backing tube is not ideal for adjusting short range magnetic field variations.

Unlike the conventional approach that involves using a non-magnetic material for the backing tube, the inventors of the instant application have realized that modifying or tuning the magnetic permeability of the backing tube, e.g., through the use of somewhat ferritic materials such as a 400 series stainless steel, would allow the target tube to act as a partial shunt along the length of the target tube. Thus, modifying or tuning the magnetic permeability of the backing tube could filter or level discrete and large short range magnetic field deviations. The inventors of the instant application have discovered this, in spite of the conventional approaches which suggest that using a magnetic backing tube is to be avoided. The magnetic permeability (as measured by relative permeability or μᵣ) of 300 series stainless steel ranges from about 1.00-8.48, with an average magnetic permeability of about 1.27, as derived from 181 of the different grades of 300 series stainless steel. By contrast, the magnetic permeability (as measured by relative permeability or μᵣ) of 400 series stainless steel ranges from about 1.02-2000, with an average magnetic permeability of about 852, as derived from 176 of the different grades of 400 series stainless steel.

The inventors of the instant application also have realized that too much magnetic permeability of the backing tube material would cause over-shunting and thus would reduce the magnetic field strength too much. However, the amount of shunting provided by the backing tube should be proportional to the deviation in or derivative (e.g., dB/dx, where x is the length dimension of the target) of magnetic field strength. Accordingly, such shunting should be most effective where large deviations in the field exist. Typically, such large deviations in the field will exist where there are short range magnetic field spikes. Thus, the magnetic material used in the backing tube and, more particularly, its magnetic permeability, may be chosen based on a number of factors. Such factors may include, for example, some or all of the magnet bar configuration, intrinsic field uniformity deviations of the magnet bar, the distance between magnet bar and target material, and/or the like. As noted above, the magnetic permeability (as measured by relative permeability or μᵣ) of 400 series stainless steel ranges from about 1.02-2000, with an average magnetic permeability of about 852, as derived from 176 of the different grades of 400 series stainless steel. The stainless steel incorporated in certain example embodiments therefore may in certain example instances have a magnetic permeability of at least about 1.3 (e.g., greater than the average magnetic permeability of 300 series stainless steel) and preferably within the above-identified range of magnetic permeability for 400 series stainless steel, depending on the above-noted and/or other influencing factors.

Thus, in certain example embodiments, backing tube alloys may be carefully optimized to be somewhat ferromagnetic, thereby enhancing the uniformity of the magnetic field generated by the magnet bar in magnetron sputtering with cylindrical sputtering targets. For example, a slightly ferromagnetic stainless steel may be used to partially shunt the magnetic field in certain example embodiments. In certain example embodiments, short range magnetic field deviations may be reduced to less than about 5% from average, more preferably to less than about 2% from average, and still more preferably to less than about 1% from average. In so doing, it is possible to finely adjust and thereby reduce short range magnetic field deviations. In certain example embodiments, the loss or attenuation of the total magnetic field preferably will be less than about 25%, more preferably less than about 20%, and still more preferably less than about 10%. Other ranges and sub-ranges of the reduction of short range magnetic field deviations and/or loss of total magnetic field also are possible in certain example embodiments.

It will be appreciated that such techniques may be used in connection with, or separate from, the shunting approach that can address long range magnetic field deviations. Although certain example embodiments have been described as including a 400 series stainless steel, it will be appreciated that any other material capable of improving or increasing short range magnetic field uniformity and/or reducing short range magnetic field deviations may be used in connection with certain other example embodiments. Similarly, the material does not necessarily need to be ferritic, provided that the material can provide the required level of shunting (e.g., for increasing short range magnetic field uniformity and/or reducing short range magnetic field deviations). Indeed, the target backing tube of certain example embodiments may comprise any material with ferromagnetic properties sufficient enough to interact with the magnet bars in a desirable manner.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A rotatable magnetron sputtering target, comprising:
a rotatable target tube comprising a target backing tube having sputtering material supported by an outer surface thereof to be sputter deposited on a substrate, the target backing tube being at least partially ferromagnetic; and
a magnet bar structure provided within the rotatable target tube, the magnet bar structure being stationary when the rotatable tube is rotating during sputtering,
wherein the target backing tube and the magnet bar structure are arranged to cooperate in producing a substantially uniform magnetic field during sputtering.

2. The sputtering target of claim 1, wherein the target backing tube has a magnetic permeability suitable for reducing short range deviations in the uniformity of the magnetic field created by the magnet bar structure.

3. The sputtering target of claim 1, wherein the target backing tube material is suitable for reducing short range magnetic field deviations to less than about 5% from the average magnetic field deviation.

4. The sputtering target of claim 1, wherein the target backing tube material is suitable for reducing short range magnetic field deviations to less than about 2% from the average magnetic field deviation.

5. The sputtering target of claim 1, wherein the target backing tube material is suitable for reducing short range magnetic field deviations to less than about 1% from the average magnetic field deviation.

6. The sputtering target of claim 1, wherein total magnetic field loss due to the ferromagnetic target backing tube material is less than about 20%.

7. The sputtering target of claim 1, wherein total magnetic field loss due to the ferromagnetic target backing tube material is less than about 10%.

8. The sputtering target of claim 1, further comprising at least one adjustment mechanism configured to alter a distance between at least a portion of the magnet bar structure and the sputtering material.

9. The sputtering target of claim 8, wherein the at least one adjustment mechanism comprises at least one shim and/or screw.

10. The sputtering target of claim 2, wherein the target backing tube material has a magnetic permeability suitable for adjusting the magnetic field uniformity within about 2 ft.

11. The sputtering target of claim 2, wherein the target backing tube material has a magnetic permeability suitable for adjusting the magnetic field uniformity within about 1 ft.

12. The sputtering target of claim 1, wherein the target backing tube comprises 400 series stainless steel.

13. A rotatable magnetron sputtering target, comprising:
a rotatable target tube comprising a target backing tube having sputtering material supported by an outer surface thereof to be sputter deposited on a substrate, the target backing tube being at least partially ferromagnetic;
a magnet bar structure provided within the rotatable target tube, the magnet bar structure being stationary when the rotatable tube is rotating during sputtering; and
at least one adjustment mechanism configured to alter a distance between at least a portion of the magnet bar structure and the sputtering material,
wherein the at least one screw or shim adjustment mechanism and the magnet bar structure are arranged to cooperate during sputtering to (a) improve or increase long range magnetic field uniformity and (b) reduce long range magnetic field deviations,
wherein the target backing tube and the magnet bar structure are arranged to cooperate during sputtering to (a) improve or increase short range magnetic field uniformity and (b) reduce short range magnetic field deviations.

14. The sputtering target of claim 13, further comprising at least two screw or shim adjustment mechanisms provided on a single side of the magnet bar structure.

15. The sputtering target of claim 14, wherein a magnetic permeability of the target backing tube material is configured to reduce magnetic field deviations between adjacent ones of said adjustment mechanisms.

16. The sputtering target of claim 13, wherein the target backing tube material is configured to reduce magnetic field deviations along a length of less than about 2 feet.

17. The sputtering target of claim 13, wherein the target backing tube material is configured to reduce magnetic field deviations along a length of less than about 1 foot.

18. The sputtering target of claim 13, wherein the target backing tube material is suitable for reducing short range magnetic field deviations to less than about 2% from the average magnetic field deviation.

19. The sputtering target of claim 13, wherein the target backing tube material is suitable for reducing short range magnetic field deviations to less than about 1% from the average magnetic field deviation.

20. The sputtering target of claim 13, wherein the target backing tube comprises 400 series stainless steel.
